(19) United States
(12) Patent Application Publication
(10) Pub. No.: US 2007/0159070 A1
(43) Pub. Date: Jul. 12, 2007

(54) Dual emission display

(75) Inventor: Min-Chieh Hu, Tainan Hsien (TW)

Correspondence Address: BIRCH STEWART KOLASCH & BIRCH, PO BOX 747, FALLS CHURCH, VA, 22040-0747, US

(73) Assignee: AU Optronics Corp.

(21) Appl. No.: 11/543,967

(22) Filed: Oct. 6, 2006

(30) Foreign Application Priority Data
Jan. 12, 2006 (TW) 95101256

(51) Int. Cl. H01L 51/00

(52) U.S. Cl. 313/504; 313/512

(57) ABSTRACT

A dual emission display includes a first substrate, and a second substrate located on the first substrate. A first organic light emitting diode is disposed on the upper surface of the first substrate, and is completely covered by a first protecting layer. A second organic light emitting diode is disposed on the lower surface of the second substrate, and is completely covered by a second protecting layer. The first protecting layer and the second protecting layer are used to isolate these organic light emitting diodes from the oxygen and the moisture.

This application claims the benefit of Taiwan Application Serial No. 095101256, filed Jan. 12, 2006, the subject matter of which is incorporated herein by reference.

### BACKGROUND OF THE INVENTION

(1) Field of the Invention

The present invention relates to a dual emission display, particularly to a dual organic electroluminescent display capable of preventing moisture and oxygen invading.

(2) Description of the Prior Art

As the electric products are getting more and more various, they emphasize the structure of two display screens. For example, a mobile phone having a dual emission display can display a main function menu at one side, and display time at the other side. Typically, the dual emission display includes two adhered single-side panels, such as a liquid crystal panel adhered to an organic electro-luminescent panel, two adhered liquid crystal panels, or two adhered organic electro-luminescent panels.

FIG. 1 shows a dual emission display according to the prior art. The dual emission display 10 includes a first display panel 11 and a second display panel 12. The first display panel 11 has a transparent substrate 111, a first electrode 112, an light emitting layer 113, a second electrode 114 and a package lid 115. The first electrode 112 is formed on the transparent substrate 111. The light emitting layer 113 is disposed between the first electrode 112 and the second electrode 114. The package lid 115 is adhered on the transparent panel 111 and covers on the second electrode 114. A dry agent 116 is disposed inside the package lid 115 to protect the first display panel 11 from moisture.

The second display panel 12 has a transparent substrate 121, a third electrode 122, an light emitting layer 123, a forth electrode 124 and a package lid 125. The third electrode 122 is formed on the transparent panel 121. The light emitting layer 123 is disposed between the third electrode 122 and the forth electrode 124. The package lid 125 is adhered on the transparent substrate 121. The package lid 115 is adhered to the package lid 125 to construct the dual emission display 10. Likewise, there is a dry agent 126 disposed inside the package lid 125.

As stated above, the typical dual emission display 10 has two package lids 115 and 125, and two dry agents 116 and 126. The dual emission display 10 is difficult to become thinner because it is difficult to reduce the distance between two transparent substrates 111 and 121. The reason is that, the display needs to increase the thickness, length or width to place the dry agent. For example, the package lids 115 and 125 is necessary to place the dry agents 116 and 126, which result in the typical dual emission display 10 increase thickness. In addition, the dry agent expands or releases some gas with absorbing moisture to make it possible to damage the light emitters.

### SUMMARY OF THE INVENTION

The object of the present invention is to provide a dual emission display capable of preventing moisture and oxygen invading, and saving the space of dry agent to be lighter and thinner.

According to the present invention, the dual emission display includes a first substrate, and a second substrate located on the first substrate. A first organic light emitting diode is disposed on the upper surface of the first substrate, and is completely covered by a first protecting layer. A second organic light emitting diode is disposed on the lower surface of the second substrate, and is completely covered by a second protecting layer. The first protecting layer and the second protecting layer are used to isolate these organic light emitting diodes from oxygen and moisture.

### BRIEF DESCRIPTION OF THE DRAWINGS

The present invention will now be specified with reference to its preferred embodiment illustrated in the drawings, in which

FIG. 1 is an dual emission display according to the prior art;

FIG. 2 is an first embodiment of the dual emission display according to the present invention;

FIG. 3 is the second embodiment of the dual emission display according to the present invention; and

FIG. 4 is the third embodiment of the dual emission display according to the present invention.

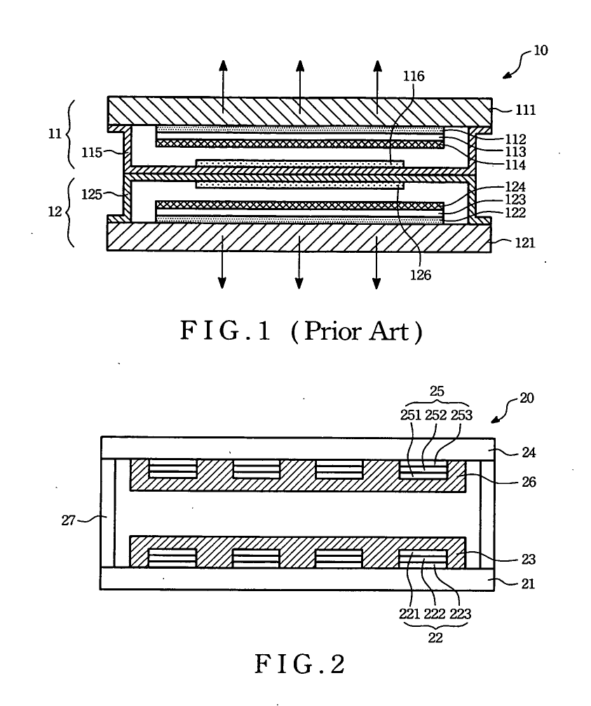

### DESCRIPTION OF THE PREFERRED EMBODIMENT

FIG. 2 shows a first embodiment according to the present invention. The dual emission display 20 includes a lower substrate 21 adhered to a upper substrate 24 with a sealant 27. The upper surface of the lower substrate 21 is mounted with a transparent electrode 223, a light emitting layer 222 and a reflective electrode 221 to construct an organic light emitting diode 22. The lower surface of the upper substrate 24 is mounted with a transparent substrate 253, a light emitting layer 252 and a reflective electrode 251 to construct another organic light emitting diode 25. The organic light emitting diodes 22 and 25 are covered by protecting layers 23 and 26 respectively, and packaged to the lower and upper substrates 21, 24 snugly.

The protecting layers 23 and 26 are capable of isolating oxygen and moisture. Preferably, the protecting layers 23 and 26 have a flat surface to prevent the step coverage. It can smoothly perform later fabricating process such as evaporation, disposition to seal the organic light emitting diodes 22 and 25 completely. The protecting layers 23 and 26 may be made of silicon nitride, silicon oxide or aluminum oxide. The protecting layers 23 and 26 are not limited to a single-layer structure. In other words, they may comprise a plurality of films, for example, the combination of a silicon oxide film, and a silicon nitride film and an aluminum oxide film, or the combination of a silicon nitride film and an aluminum oxide film and so on.

A hole or electron passing area is between the electrodes and the light emitting layer. In the hole passing area, a hole injecting layer (not shown) or a hole transporting layer (not shown) is interposed selectively. In the electron passing area, an electron injecting layer (not shown) or an electron transporting layer (not shown) is interposed selectively.

The electron transporting layer may be made of (8-hydroxyquinolinolato)aluminum (Alq), 1,3,5-Tris (N-phenylbenzimidazol-2-yl)benzene (TPBI), derivatives of anthracene, or derivatives of fluorine, spirofluorine etc., mixed with n-type dopant such as alkali halides, alkaline-earth halides, alkali oxides or metal-carbonate compound etc. to increase electron mobility thereof.

The electron injecting layer may be made of metal compound with work function perfectly adapted to that of the non-transparent electrode, such as alkali halides, alkaline-earth halides, alkali oxides or metal-carbonate compound, or an organic layer mixed with such n-type dopants.

The hole transporting layer may be made of allylamine group material such as N,N-di(naphthalene-1-yl)-N,N-diphenyl-benzidene (NPB).

The hole injecting layer may be made of allylamine group material, or phthalocyanine group material such as CuP.

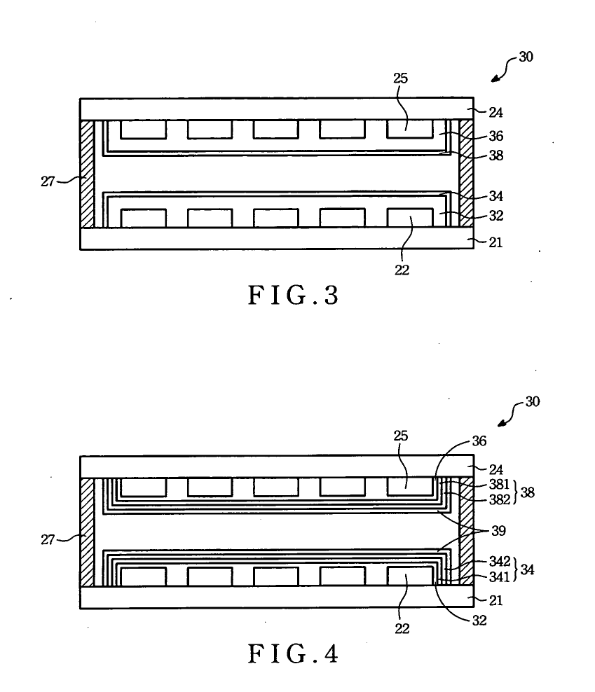

The protecting layer is not only flattened as the first embodiment, but also independent of the flat layer as the second embodiment shown in FIG. 3. The dual emission display 30 includes the lower substrate 21, the upper substrate 24, the sealant 27, the organic light emitting diodes 22 and 25, the related position of which is described as FIG. 2. The difference between the two embodiments is that, flat layers 32, 36 are added between the protecting layers 34, 38 and the organic light emitting diodes 22, 25. The flat layers 32, 36 may be made of polymers or inorganic materials. The flat layers 32, 36 avoid not only covering insufficiency of the protecting layers 34 and 38 due to the step coverage, but also the low producing yield due to the larger inner stress of the protecting layers 34 and 38.

Preferably, the flattened protecting layers or flat layers slope ranging from positive 60 degree to negative 60 degree. In the surface of the flattened protecting layers or the flat layers, a highest point is 5 μm or below away from a lowest point. The flat layers may be made of a moisture resistant material such as silicon nitride, silicon oxide or aluminum oxide.

FIG. 4 shows the third embodiment of the present invention. The protecting layers 34 may be made from a single silicon oxide film 341, or a combination of silicon oxide films 381 and silicon nitride films 382. In addition, an aluminum oxide film 39 covers the protecting layers 34 and 38.

In the third embodiment, the organic light emitting diode 22 is fabricated by forming the transparent electrode 223, the light emitting layer 222 and the reflective electrode 221 in order as shown in FIG. 2. A polymer acts as the flat layer 32 and deposited on the organic light emitting diode 22. Subsequently, the silicon nitride film 341 is formed on the entire flat layer 32. The silicon oxide film 342 is formed on the entire silicon nitride film 341. The aluminum oxide 39 is formed on the entire silicon oxide film 342.

The same process is performed on another substrate 24. The organic light emitting diode 25, the flat layer 36, the silicon nitride film 381, silicon oxide film 382 and the aluminum film 39 are formed in order. For displaying two different images on two side of the dual emission display 30 simultaneously, two independent driving circuits are disposed on the substrates 21 and 24, respectively. The substrates 21 and 24 are combined via the sealant 27 to form the dual emission display 30. The above structure may be produced by evaporation. The whole-surface evaporation is used in fabricating process except the stage of forming the organic light emitting diode 22, which needs photomask to perform pattering. That is the reason why the fabricating process can be simplified.

Above mentioned, the transparent electrode can made of metals or the transparent conductive materials such as ITO, IZO. The transparent substrate can be made of glass or plastic material. The application of the present is not limited to passive or active displays. It is possible to co-operate with driving components such as thin film transistors.

In comparison with the prior art, the present invention have the advantages of preferred moisture and oxygen resistance, and simpler fabricating process.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A dual emission display, comprising:
a first substrate;
a first organic light emitting diode disposed on the upper surface of the first substrate;
a first protecting layer covering the entire surface of the first organic light emitting diode;
a second substrate located on the first substrate;
a second organic light emitting diode disposed on the lower surface of the second substrate; and
a second protecting layer covering the entire surface of the second organic light emitting diode.

2. The dual emission display of claim 1, wherein the first protecting layer has a flat upper surface.

3. The dual emission display of claim 2, wherein the second protecting layer has a flat lower surface.

4. The dual emission display of claim 1, wherein at lease one of the first and second protecting layers is made of a material selected from the group consisting of silicon nitride, silicon oxide, and aluminum oxide.

5. The dual emission display of claim 1, wherein the first protecting layer is made of a plurality of films having at least one of a silicon oxide and a silicon nitride.

6. The dual emission display of claim 5, wherein the second protecting layer is made of a plurality of films having at least one of a silicon oxide and a silicon nitride.

7. The dual emission display of claim 1, wherein the first organic light emitting diode includes:
a transparent electrode formed on the upper surface of the first substrate;
an light emitting layer formed on the transparent electrode; and
a reflective electrode formed on the light emitting layer.

8. The dual emission display of claim 1, wherein the second organic light emitting diode includes:
a transparent electrode formed on the lower surface of the second substrate;
an light emitting layer formed on the transparent electrode; and
a reflective electrode formed on the light emitting layer.

9. A dual emission display, comprising:
a first substrate;
a first organic light emitting diode disposed on the upper surface of the first substrate;
a first flat layer formed on the first organic light emitting diode;
a first protecting layer covering the entire surface of the first flat layer;
a second substrate located on the first protecting layer;
a second organic light emitting diode disposed on the lower surface of the second substrate; and
a second flat layer formed on the organic light emitting diode; and
a second protecting layer covering the entire surface of the second organic light emitting diode.

10. The dual emission display of claim 9, wherein the first and second protecting layers are both made of a plurality of films having at least one of a silicon oxide and a silicon nitride.

11. The dual emission display of claim 10, wherein the silicon nitride of the first protecting layer is formed on the first flat layer, and the silicon nitride of the second protecting layer is formed on the second flat layer.

12. The dual emission display of claim 11, wherein the silicon oxide of the first protecting layer is formed on the silicon nitride, and the silicon oxide of the second protecting layer is formed on the silicon nitride.

13. The dual emission display of claim 12, further comprising an aluminum oxide film formed on the surface of the silicon nitride.

14. The dual emission display of claim 9, wherein at least one of the first and second flat layers has a flatness less than 5 μm.

15. The dual emission display of claim 9, wherein at least one of the first and second flat layers has a slope ranging from positive 60 degree to negative 60 degree.

16. The dual emission display of claim 9, wherein the first flat layer includes a polymer.

17. The dual emission display of claim 16, wherein the second flat layer includes a polymer.

18. The dual emission display of claim 9, wherein the first flat layer includes silicon oxide.

19. The dual emission display of claim 18, wherein the second flat layer includes silicon oxide.
